(19) United States
(12) Patent Application Publication
(10) Pub. No.: US 2026/0265045 A1
(43) Pub. Date: Sep. 10, 2026

(54) ULTRASONIC TRANSCEIVER WITH STACKED DIE BACK CAVITY

(71) Applicant: InvenSense, Inc., San Jose, CA (US)

(72) Inventors: Richard Przybyla, Piedmont, CA (US); Benjamin Eric Eovino, Oakland, CA (US); Stefon Eric Shelton, Oakland, CA (US)

(21) Appl. No.: 19/555,057

(22) Filed: Mar. 3, 2026

Related U.S. Application Data
(60) Provisional application No. 63/767,674, filed on Mar. 6, 2025.

(51) Int. Cl. B81B 3/00

(52) U.S. Cl. CPC B81B 3/0021; B81B 2201/0271; B81B 2203/0127; B81B 2203/0315; B81B 2207/03; B81B 2207/056

(57) ABSTRACT

An ultrasonic transceiver includes a microelectromechanical system (MEMS) substrate having a micromachined ultrasonic transducer (MUT) suspended over a front cavity that is exposed to an external environment through an acoustic port. A semiconductor substrate includes a MEMS cap that is physically secured relative to the MEMS substrate, overlies the MUT, and defines a back cavity on an opposite side of the MUT from the front cavity, the back cavity enclosing an air volume.

### CROSS-REFERENCE TO RELATED APPLICATION

This application claims priority to U.S. Provisional Patent Application No. 63/767,674, filed March 6, 2025, and entitled “Ultrasonic Transceiver with a Stacked Die Back Cavity,” which is incorporated by reference herein in its entirety for all purposes.

### BACKGROUND

Ultrasonic transceivers that include micromachined ultrasonic transducers (“MUTs”), such as piezoelectric micromachined ultrasonic transducers (“PMUTs”), transmit ultrasonic signals into an environment of interest and in some implementations receive reflected or otherwise returned ultrasonic waves. Characteristics of a received ultrasonic signal, such as timing, phase, and magnitude, can be processed to determine distance (e.g., time-of-flight), presence, motion, and/or other characteristics of an object or medium of interest.

Ultrasonic transceivers are typically packaged with processing circuitry such as an application specific integrated circuit (“ASIC”) adjacent to the ultrasonic transceiver that controls the transmission and reception of ultrasonic signals and provides processing for these signals. These ultrasonic transceiver packages are utilized in a wide variety of end-use devices and applications, positioned in a manner such that an access port for the transmission and reception of the ultrasonic signals is exposed to an environment of interest. In some applications, it may be desirable to provide an ultrasonic transceiver having a reduced lateral footprint while preserving acoustic access to the ultrasonic transceiver.

### SUMMARY

According to an example embodiment, an ultrasonic transceiver includes a microelectromechanical system (MEMS) substrate and a semiconductor substrate. The MEMS substrate includes a micromachined ultrasonic transducer (MUT) suspended over a front cavity in the MEMS substrate that is exposed to an external environment. The semiconductor substrate includes a cap that is physically secured relative to the MEMS substrate, overlying the MUT, and defining a back cavity that encloses an air volume and is located on an opposite side of the MUT from the front cavity.

In another example embodiment, a method for fabricating an ultrasonic transceiver includes providing a microelectromechanical system (MEMS) substrate and a semiconductor substrate. The microelectromechanical system (MEMS) substrate includes a micromachined ultrasonic transducer (MUT) suspended over a front cavity in the MEMS substrate, the front cavity being configured to be exposed to an external environment. The semiconductor substrate includes a cap defining a cavity recess. The semiconductor substrate is positioned such that the semiconductor substrate overlies the MUT. The semiconductor substrate is physically secured relative to the MEMS substrate such that the cap cooperates with the MEMS substrate to define a back cavity that forms an air volume on an opposite side of the MUT from the front cavity.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative ultrasonic transceiver system in accordance with an embodiment of the present disclosure;

FIG. 2 depicts an exemplary ultrasonic transceiver including a stacked cap with an inactive layer and a processing circuitry layer defining a back cavity in accordance with an embodiment of the present disclosure;

FIG. 3 depicts an exemplary ultrasonic transceiver including a stacked cap including processing circuitry defining a back cavity in accordance with an embodiment of the present disclosure;

FIG. 4 depicts an exemplary ultrasonic transceiver including a stacked cap defining a back cavity and overmold in accordance with an embodiment of the present disclosure;

FIG. 5 depicts an exemplary ultrasonic transceiver including a multi-level stacked cap defining a back cavity in accordance with an embodiment of the present disclosure;

FIG. 6 depicts an exemplary ultrasonic transceiver including a stacked cap with processing circuitry defining a back cavity and overmold in accordance with an embodiment of the present disclosure;

FIG. 7 depicts an exemplary ultrasonic transceiver including a stacked cap with an inactive layer and processing circuitry defining a back cavity and overmold in accordance with an embodiment of the present disclosure; and

FIG. 8 depicts exemplary steps of a fabrication process for an ultrasonic transceiver in accordance with embodiments of the present disclosure.

### DETAILED DESCRIPTION

Ultrasonic transceivers are devices that emit and detect sound waves at frequencies above the range of human hearing. In operation, an ultrasonic transceiver converts electrical energy into ultrasonic vibrations that propagate through a surrounding medium (such as air) and then converts returned vibrations back into electrical signals. The returned signals can be from a variety of sources in the external environment such as echoes reflected from nearby objects, scattered energy from surfaces, or transmitted energy passing through a material. By measuring characteristics of the returned ultrasonic signals (e.g., when they arrive, how strong they are, and how their phase or frequency changes), processing circuitry can determine information about the environment, including the presence of an object, its distance, its motion, and in some cases properties of its surface or of the surrounding medium. Example uses of these transceivers include ranging, presence detection, gesture sensing, or environmental monitoring.

Many modern ultrasonic transceivers rely on micromachined ultrasonic transducers, often abbreviated as “MUTs.” A MUT is typically fabricated using microelectromechanical systems (MEMS) techniques, such that it can include a very small movable membrane formed on a substrate. When driven by an electrical signal, the membrane vibrates and generates ultrasonic waves. When ultrasonic waves return and strike the membrane, the membrane’s motion produces a corresponding electrical signal. MUTs can be implemented using different operating principles. For example, in a piezoelectric MUT (PMUT), a piezoelectric material produces electrical charge when strained and conversely strains when an electric field is applied. In a capacitive MUT (CMUT), a change in spacing between conductive elements changes capacitance, enabling conversion between electrical signals and mechanical vibration. Regardless of the specific implementation, the fundamental operation involves a mechanical membrane that interacts with the surrounding air or other medium.

A packaged ultrasonic transceiver generally has two distinct cavities adjacent to the MUT membrane. On one side of the membrane is a front cavity that is accessible to the external environment and through which the MUT communicates ultrasonic signals with that external environment, so that ultrasonic waves can travel out of and into the device. This front cavity is accessible to the external environment through an opening, which can be referred to as an acoustic port, that is formed in a supporting substrate such as a land-grid array (“LGA”) substrate that provides physical support for the MUT and electrical connections to other components of the of the end-use device. On the opposite side of the membrane is a back cavity. The back cavity is enclosed, and its volume, gas content, and geometry influence how easily the membrane can move and how acoustic energy behaves within the package, including acoustic resonance modes for the sensor. Processing circuitry for the MUT is typically located within the back cavity adjacent to the MUT (e.g.¸ on a surface of the LGA substrate) and takes up substantial space within the back cavity, impacting the acoustic characteristics of the back cavity. Depending on the characteristics of the front and back cavity, the MUT may have acoustic resonance modes that interfere with the operating range of the ultrasonic signals and reflections of interest, and must be accommodated with design or operational constraints to avoid those acoustic resonance modes.

The disclosed embodiments address these packaging and integration challenges by arranging the transceiver’s components in a stacked structure that preserves both acoustic functionality and compactness. In the disclosed transceivers, a MEMS substrate supports the MUT membrane and defines a front cavity that is exposed to the external environment, such as through an opening in a LGA substrate. A semiconductor substrate (e.g., as an ASIC substrate or an ASIC substrate combined with a non-active cap) can be physically secured above the MEMS substrate and overlies the MUT, rather than being located adjacent to the MUT such as on the LGA substrate upper surface. This upper semiconductor substrate defines a controlled back cavity located on the opposite side of the MUT from the front cavity. Other arrangements can include a separate ASIC die and no circuitry in the cap.

Because the stacked back-cavity is defined by one or more additional semiconductor layers, the back cavity characteristics can be precisely tuned for desired operational characteristics. For example, a back-cavity volume, a back-cavity height (e.g., a standoff distance between the MUT membrane and an opposing cavity surface), back cavity air pressure, and a lateral extent of the back cavity are selected together to tune a target receive bandwidth and to select the frequencies of acoustic resonance modes (e.g., within a known range of frequencies) such that the operating range of the ultrasonic sensor is unlikely to overlap with the acoustic resonance modes (e.g., by having no acoustic resonance modes within the operating frequency range or only having a limited subset of acoustic resonance modes with known response characteristics). This allows the MUT to operate within its full operational range and limits the need to engage in mitigation strategies, which may require additional processing resources, can impact accuracy, may require an increase in package size, or in some instances, may not be effective for a particular MUT design. In some embodiments, the back cavity includes one or more damping or mode-shaping features.

The semiconductor substrate can include or support processing circuitry such as electronic circuits of an ASIC that drive the MUT in transmit and process the received signals in receive. By placing this semiconductor substrate above the MEMS substrate, rather than positioning it laterally beside the MEMS die, the overall lateral footprint can be reduced because circuitry is moved into the vertical dimension. In certain embodiments, the processing circuitry substrate itself defines the back cavity via a recess and a perimeter seal, while in other embodiments a non-active substrate such as a MEMS cap forms the cavity and the processing circuitry substrate is stacked above or bonded to the non-active cap. In still other embodiments, a monolithic semiconductor substrate includes both a circuit-containing portion and a cavity-defining portion formed in the same body.

The disclosed embodiments also contemplate packaging approaches that improve robustness and manufacturability while preserving the integrity of the air-filled back cavity. For example, in some embodiments the stacked substrates are surrounded by a lid coupled to the LGA board, providing mechanical protection and environmental isolation. In other embodiments, the stacked substrates are encapsulated in an overmold compound, which can help reduce lateral dimensions and production cost, as well as reduce part count and improve shock and drop resistance. Certain embodiments further provide a semiconductor substrate that extends laterally beyond the perimeter of the MEMS substrate and forms a surrounding wall. That surrounding wall can act as a structural barrier and a stress-isolation feature that decouples molding-induced and board-level mechanical stress from the MEMS region. This configuration can be particularly beneficial when overmolding is used, because it can reduce the transfer of molding-induced mechanical stress to sensitive MEMS regions and can help maintain a stable cavity boundary.

The stacked semiconductor layers further provide for precise control of the air content and pressure within the back cavity, such that in some embodiments the back volume does not need to be processed at vacuum. The disclosed air-filled back cavity architectures can further improve manufacturability and long-term reliability relative to vacuum-cavity approaches. In particular, sealing a non-vacuum cavity can be more tolerant of minor seal leakage or outgassing over time, as small pressure variations within an air-filled cavity generally produce less abrupt changes in membrane behavior than comparable leakage in a vacuum cavity. In addition, the choice of back cavity allows tuning of the damping of the PMUT membrane.

In some embodiments multiple MEMS substrates are stacked, each with its own MUT, separated by a controlled spacing. Spacing can be chosen to be a specific fraction of a wavelength of the ultrasonic wave, chosen such that the signals received from the transducers add constructively during receive, and that the driving signals add constructively at the transducers sound port, thereby improving the signal-to-noise ratio relative to a single-MUT configuration. Vertical stacking of MUTs can provide this performance improvement without increasing lateral footprint, which can be particularly advantageous in space-constrained modules where lateral area is more limited than vertical height. In addition, vertical stacking can simplify alignment relative to a common acoustic axis compared to laterally distributed arrays. Additionally, a stacked die arrangement can provide simplified alignment to a common acoustic port. This provides an additional performance improvement that can be achieved without increasing lateral footprint, because the additional transducer is placed in the vertical stack. Collectively, these structures and packaging techniques provide a set of practical, manufacturable architectures for compact ultrasonic transceivers that preserve acoustic access to the environment, define an intentional air-filled back cavity, and integrate the necessary electronic circuits in a space-efficient and mechanically robust manner.

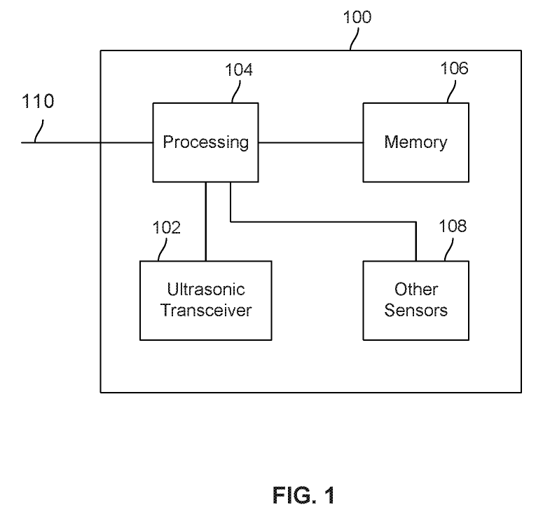

FIG. 1 shows an illustrative ultrasonic transceiver system 100 in accordance with an embodiment of the present disclosure. Although particular components are depicted in FIG. 1, it will be understood that other suitable combinations of ultrasonic transceivers, other sensors, processing components, memory, and other circuitry can be utilized as necessary for different applications and systems. In accordance with the present disclosure, the ultrasonic transceiver system 100 can include an ultrasonic transceiver 102, processing circuitry, memory, as well as additional sensors 108.

Processing circuitry 104 can include one or more components providing processing based on the requirements of the ultrasonic transceiver system 100. In some embodiments, processing circuitry 104 can include hardware control logic integrated within a chip of the ultrasonic transceiver 102 (e.g., on a die associated with the ultrasonic transceiver 102) to control operation of the ultrasonic transceiver 102 and to perform aspects of signal generation and signal processing. In some embodiments, processing circuitry 104 can include a processor such as a microprocessor that executes software instructions stored in memory 106. The microprocessor can control operation of the ultrasonic transceiver 102 by interacting with hardware control logic and by processing signals received from the ultrasonic transceiver 102. The microprocessor can interact with other sensors 108 in a similar manner. In some embodiments, some or all of the functions of the processing circuitry 104, and in some embodiments, of memory 106, can be implemented on an application specific integrated circuit (“ASIC”) and/or a field programmable gate array (“FPGA”).

Although in some embodiments (not depicted in FIG. 1), the ultrasonic transceiver 102 or other sensors 108 can communicate directly with external circuitry (e.g., via a serial bus or direct connection to sensor outputs and control inputs), in an embodiment the processing circuitry 104 can process data received from the ultrasonic transceiver 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 can convert signals received from the ultrasonic transceiver 102 and other sensors 108 into appropriate measurement units (e.g., based on settings provided by other computing units communicating over the communication interface 110).

In a typical ultrasonic transceiver the back cavity can be defined by a lid (e.g., a metallic lid) and other components located within the back cavity, such as an ASIC, wirebonds, potting, and the like. Due to the typical processing controls for applying and locating the lid and components within the lid, acoustic resonance modes may vary under typical process and fabrication conditions. In many instances of a typical back cavity construction, one or more acoustic resonance modes may be at frequencies that are within the operating range of the ultrasonic system due to the relatively large back cavity volume, requiring mitigation measures such as limiting operations at or adjacent to the frequencies associated with the acoustic resonance modes or restricting the package to specific cavity designs and dimensions that decouple the acoustic mode from the ultrasonic transceiver, for example, by designing the packaging and cavity such that the acoustic resonance modes are centered on the MUT membrane, resulting in a zero net pressure over the membrane at the acoustic resonance mode.

In accordance with the present disclosure, the back cavity is defined by a semiconductor layer that provides the ability to reduce the cavity dimensions, and may also have much less process variability than a typical lid, wire bonds, potting, and other components associated with a typical back cavity. Accordingly, the acoustic resonance modes can be better defined and in some embodiments the back cavity design can be controlled in a manner (e.g., based on volume, shape, pressure, height, etc.) that entirely moves the frequencies of the acoustic resonance modes outside of an operating frequency range of the ultrasonic sensor. In some embodiments, the cavity geometry and volume are selected such that a primary back-cavity resonance frequency lies outside a principal operating frequency band of the MUT. In additional embodiments, the back cavity is formed with substantially symmetric geometry relative to a center of the MUT membrane, and the membrane is positioned at or near a pressure node of a dominant cavity mode such that the average pressure across the membrane surface is close to zero (i.e., approximately zero). In this manner, a negligible portion of the overall signal power used for transmission and reception of acoustic signals via the membrane is consumed by exciting the acoustic resonance mode. Accordingly, the embodiments of the present disclosure may be utilized to control acoustic resonance mode characteristics over the MUT as is described in U.S. Patent Application No. 18/902,498, titled “Ultrasonic Sensor Package with Decoupled Acoustic Modes” and filed on September 30, 2024, and U.S. Provisional Patent Application No. 63/587,740, titled “PMUT Package with Decoupled Acoustic Modes” and filed on October 4, 2023, both of which are incorporated by reference in their entireties for all purposes.

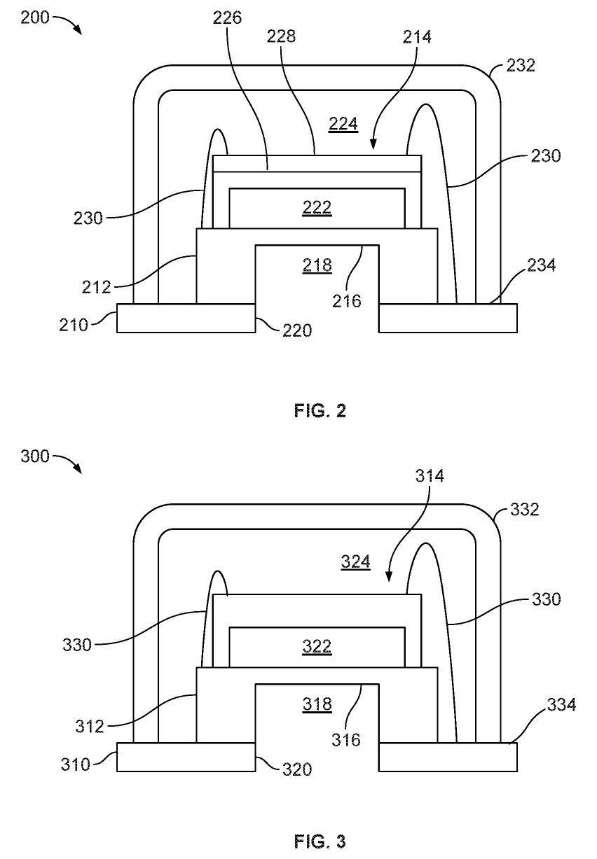

The ultrasonic transceiver 102 can be implemented in a stacked-substrate package architecture as described in further detail below with reference to FIGS. 2–7, in which a semiconductor substrate overlies a MEMS substrate including a MUT, and a back cavity enclosing an air volume is defined on an opposite side of the MUT membrane from a front cavity exposed to an external environment. In some embodiments, the ultrasonic transceiver package architecture can be categorized based on a lateral footprint relationship between a semiconductor substrate and a MEMS substrate. In one arrangement, the semiconductor substrate overlies the MEMS substrate and has a lateral extent that is contained within an outer lateral perimeter of the MEMS substrate. In another arrangement, the semiconductor substrate overlies the MEMS substrate and has a lateral extent that extends beyond the outer lateral perimeter of the MEMS substrate such that the semiconductor substrate laterally surrounds at least a portion of the MEMS substrate (e.g., it is concentric). In some embodiments of the concentric arrangement, the semiconductor substrate defines a wall surrounding the MEMS substrate and a back cavity that surrounds the outer lateral perimeter of the MEMS substrate.

As used herein, “physically secured” includes direct bonding, indirect bonding through intermediate layers, and attachment via package structures.

As used herein, an “air volume” refers to a gas-filled volume that contains air (or an air-like gas mixture) at a non-vacuum pressure. In some embodiments, the air volume can be sealed or vented (e.g., providing venting through ventholes in the PMUT) and can have an internal pressure that is approximately atmospheric pressure. In other embodiments, the air volume can be a controlled-pressure volume that remains materially greater than a vacuum pressure. An “air volume” as used herein expressly excludes a “vacuum,” which refers to a substantially evacuated cavity.

As used herein, “overlies” does not require direct contact and includes embodiments with direct contact, as well as embodiments in which an intermediate layer (e.g., adhesive, underfill, seal material, spacer, redistribution layer, or interposer) is disposed between the semiconductor substrate and the MEMS substrate. In some embodiments, the semiconductor substrate overlies at least a majority of a lateral area of the MUT membrane region. In other embodiments, the semiconductor substrate overlies the MUT membrane region and extends laterally beyond the MUT membrane region to define at least a portion of a surrounding cavity boundary.

In some embodiments, the gas within the air volume comprises ambient air. In other embodiments, the gas comprises an inert gas or controlled mixture (e.g., nitrogen, argon, helium, dry air, or mixtures thereof) selected to reduce oxidation, reduce humidity, or tune acoustic impedance and damping. In some embodiments, the air volume is sealed during bonding at a selected chamber pressure.

As used herein, a “semiconductor substrate” includes a cap that is physically secured relative to the MEMS substrate and that defines at least a portion of the back cavity. In some embodiments, the semiconductor substrate comprises: (i) a non-active semiconductor substrate that is formed such as by MEMS processes (a MEMS cap); and/or (ii) an active substrate (e.g., an ASIC die) including processing circuitry such as electronic circuits for driving the MUT and/or processing received signals. In some embodiments, the semiconductor substrate comprises a monolithic semiconductor body having a first portion including electronic circuits and a second portion that forms the cap and defines at least a portion of the back cavity. Accordingly, depending on the embodiment, the “semiconductor substrate” can function as a cap that corresponds to an active substrate (e.g., an ASIC), an inactive substrate (e.g., a MEMS cap), or various combinations thereof.

FIG. 2 depicts an exemplary ultrasonic transceiver including a stacked cap with inactive circuitry and processing circuitry defining a back cavity in accordance with an embodiment of the present disclosure. In the exemplary embodiment of FIG. 2, an ultrasonic transceiver 200 includes a land grid array (“LGA”) board 210, a MEMS substrate 212, and a semiconductor substrate 214 stacked above the MEMS substrate 212, although it will be understood that components such as intervening layers or bonding layers may not be depicted, and that components may be added or removed. The MEMS substrate 212 can include a micromachined ultrasonic transducer (“MUT”) 216 suspended over a front cavity 218 in the MEMS substrate 212. The front cavity 218 can be exposed to an external environment through an acoustic port 220 extending through the LGA board 210. In some embodiments, the ultrasonic transceiver 200 is implemented in a stacked arrangement in which the semiconductor substrate 214 overlies the MEMS substrate 212 and a lateral extent of the semiconductor substrate 214 is contained within an outer lateral perimeter of the MEMS substrate 212.

The semiconductor substrate 214 can overlie the MUT 216 and define a back cavity 222 located on an opposite side of the MUT 216 from the front cavity 218. The back cavity 222 can enclose an air volume. In some embodiments, the air volume is sealed at approximately atmospheric pressure. In some embodiments the back cavity air volume is vented to atmosphere (e.g., through holes in the MUT). In some embodiments, the air volume is sealed at a controlled pressure that is greater than vacuum and selected to tune acoustic loading and/or the compliance of the MUT 216.

In some embodiments, the semiconductor substrate 214 is a monolithic substrate including a non-active semiconductor substrate 226 portion and an active substrate 228 portion stacked on the non-active substrate. The non-active semiconductor substrate 226 can function as a cap and be created by MEMS processes (e.g., a MEMS cap) or other semiconductor manufacturing processes, and can be attached to the MEMS substrate 212 such as by a direct bonded or stacked coupling (e.g., with one or more intervening semiconductor or other layers (not depicted). An exemplary bonded coupling can include an adhered coupling (e.g., epoxy or polymer adhesive), a solder coupling, a eutectic coupling, glass frit bonding, anodic bonding, fusion bonding, or another suitable bond (e.g., glue). In some embodiments, the attachment coupling defines a perimeter seal (e.g., a continuous ring) around the back cavity 222 such that the air volume is enclosed and remains stable over time.

The active substrate 228 can be a processing layer including electronic circuits, for example, implemented as an ASIC substrate that includes electronic circuits for driving the MUT 216 and/or receiving and processing signals from the MUT 216. For example, the electronic circuits can include a high-voltage or high-current driver (for transmit), a low-noise amplifier (for receive), a time-to-digital converter or phase measurement circuitry (for time-of-flight), analog-to-digital conversion, digital filtering, and/or control logic. In some embodiments, signal routing between the semiconductor substrate 214, the MEMS substrate 212, and the LGA board 210 is provided by wirebonds 230 and/or redistribution layers, through-substrate vias, or combinations thereof (not shown in FIG. 2).

The ultrasonic transceiver 200 can additionally include a lid 232 surrounding the MEMS substrate 212 and the semiconductor substrate 214 and physically coupled to an upper surface 234 of the LGA board 210 and defining a sealed enclosure 224. In some embodiments, the air volume defined by the enclosure 224 can be vented, such as through vent holes in the MUT 216. The lid 232 can provide mechanical protection, can mitigate contamination, and can provide a stable package volume for reliability under handling and environmental stress.

The stacked configuration of the semiconductor substrate 214 over the MEMS substrate 212 can reduce lateral footprint relative to side-by-side die placement because the circuit-containing semiconductor area overlies the MEMS area rather than being located within a back cavity defined by the lid 232. The back cavity 222 can be formed directly above the MUT 216 while preserving the front cavity 218 and port 220 acoustic access. In addition, the lid 232 can provide a robust outer protection structure while allowing the internal stacked structure to be assembled using established packaging processes. Further, by utilizing highly controllable semiconductor fabrication processes to define the back cavity, the acoustic characteristics of the ultrasonic sensor can be modified such as to define resonance frequencies of the acoustic back cavity that are outside of the operating frequencies of the sensor.

FIG. 3 depicts an exemplary ultrasonic transceiver including a stacked cap including processing circuitry defining a back cavity in accordance with an embodiment of the present disclosure. In the embodiment of FIG. 3, an ultrasonic transceiver 300 includes a land grid array (“LGA”) board 310, a MEMS substrate 312, and a semiconductor substrate 314 stacked above the MEMS substrate 312, although it will be understood that components such as intervening layers or bonding layers may not be depicted, and that components may be added or removed. The MEMS substrate 312 can include a micromachined ultrasonic transducer (“MUT”) 316 suspended over a front cavity 318 in the MEMS substrate 312. The front cavity 318 can be exposed to an external environment through an acoustic port 320 extending through the LGA board 310. In some embodiments, the ultrasonic transceiver 300 is implemented in a stacked arrangement in which the semiconductor substrate 314 overlies the MEMS substrate 312 and a lateral extent of the semiconductor substrate 314 is contained within an outer lateral perimeter of the MEMS substrate 312.

The semiconductor substrate 314 can overlie the MUT 316 and define a back cavity 322 located on an opposite side of the MUT 316 from the front cavity 318. The back cavity 322 can enclose an air volume. In some embodiments, the air volume is sealed at approximately atmospheric pressure. In some embodiments the back cavity air volume is vented to atmosphere (e.g., through holes in the PMUT). In some embodiments, the air volume is sealed at a controlled pressure that is greater than vacuum and selected to tune acoustic loading and/or the compliance of the MUT 316.

In some embodiments, the semiconductor substrate 314 is formed of an active semiconductor substrate including processing circuitry such as electric circuits. The active semiconductor substrate portion functions as a cap and is attached to the MEMS substrate 312 such as by a bonded coupling, although the coupling can be created via one or more intermediate layers (not depicted). The active substrate portion can be an ASIC substrate that includes electronic circuits for driving the MUT 316 and/or receiving and processing signals from the MUT 316. For example, the electronic circuits can include a high-voltage or high-current driver (for transmit), a low-noise amplifier (for receive), a time-to-digital converter or phase measurement circuitry (for time-of-flight), analog-to-digital conversion, digital filtering, and/or control logic. In some embodiments, signal routing between the semiconductor substrate 314, the MEMS substrate 312, and the LGA board 310 is provided by wirebonds 330 and/or redistribution layers, through-substrate vias, or combinations thereof (not shown in FIG. 3).

The ultrasonic transceiver 300 can additionally include a lid 332 surrounding the MEMS substrate 312 and the semiconductor substrate 314 and physically coupled to an upper surface 334 of the LGA board 310 and defining a sealed enclosure 324. In some embodiments, the air volume defined by the enclosure 324 can be vented, such as through vent holes in the MUT 316. The lid 332 can provide mechanical protection, can mitigate contamination, and can provide a stable package volume for reliability under handling and environmental stress.

The stacked configuration of the semiconductor substrate 314 over the MEMS substrate 312 can reduce lateral footprint relative to side-by-side die placement because the circuit-containing semiconductor area overlies the MEMS area. The back cavity 322 can be formed directly above the MUT 316 while preserving the front cavity 318 and port 320 acoustic access. In addition, the lid 332 can provide a robust outer protection structure while allowing the internal stacked structure to be assembled using established packaging processes. Further, by utilizing highly controllable semiconductor fabrication processes to define the back cavity, the acoustic characteristics of the ultrasonic sensor can be modified such as to define acoustic resonance frequencies that are outside of the operating frequencies of the sensor.

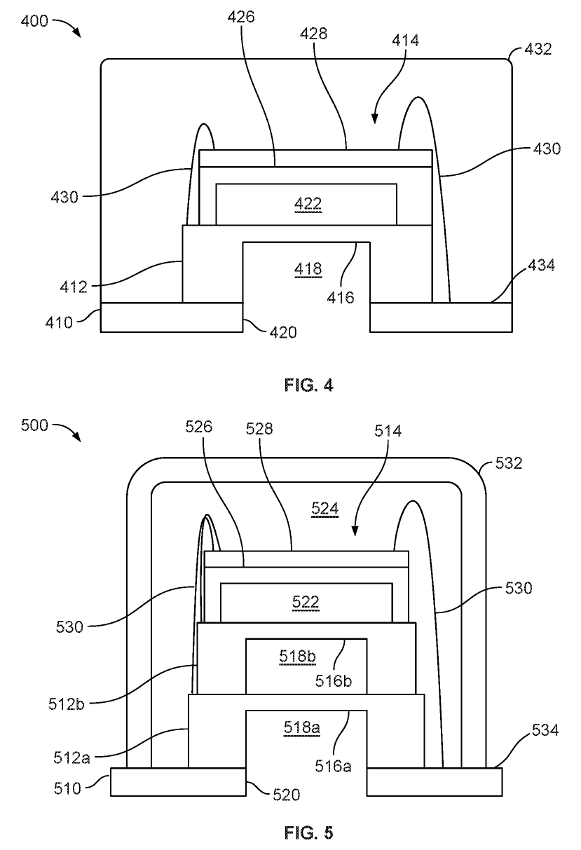

FIG. 4 depicts an exemplary ultrasonic transceiver including a stacked cap defining a back cavity and overmold in accordance with an embodiment of the present disclosure. In the embodiment of FIG. 4, an ultrasonic transceiver 400 includes a land grid array (“LGA”) board 410, a MEMS substrate 412, and a semiconductor substrate 414 stacked above the MEMS substrate 412, although it will be understood that components such as intervening layers or bonding layers may not be depicted, and that components may be added or removed. The MEMS substrate 412 includes a micromachined ultrasonic transducer (“MUT”) 416 suspended over a front cavity 418 in the MEMS substrate 412. The front cavity 418 is exposed to an external environment through an acoustic port 420 extending through the LGA board 410. In some embodiments, the ultrasonic transceiver 400 is implemented in a stacked arrangement in which the semiconductor substrate 414 overlies the MEMS substrate 412 and a lateral extent of the semiconductor substrate 414 is contained within an outer lateral perimeter of the MEMS substrate 412.

The semiconductor substrate 414 can overlie the MUT 416 and define a back cavity 422 located on an opposite side of the MUT 416 from the front cavity 418. The back cavity 422 can enclose an air volume. In some embodiments, the air volume is sealed at approximately atmospheric pressure. In some embodiments, the air volume is sealed at a controlled pressure that is greater than vacuum and selected to tune acoustic loading and/or the compliance of the MUT 416. In some embodiments, the air volume of the back cavity can be vented, such as through vent holes in the MUT 416.

In some embodiments, similar to FIG. 2, the semiconductor substrate 414 includes a non-active semiconductor substrate 426 and an active substrate 428 stacked on the non-active substrate. The non-active semiconductor substrate 426 can form a MEMS cap coupled to the MEMS substrate 412 such as by a bonded coupling. Signal routing between the semiconductor substrate 414, the MEMS substrate 412, and the LGA board 410 is provided by wirebonds 430 and/or redistribution layers, through-substrate vias, or combinations thereof (not shown in FIG. 4).

In some embodiments, the bonded coupling defines a perimeter seal (e.g., a continuous ring) around the back cavity 422 such that the air volume is enclosed and remains stable over time. In some embodiments, the air volume can be vented to correspond to the pressure in the external environment, such as through vent holes in the MUT. In alternate embodiments, similar to FIG. 3, the semiconductor substrate 414 includes is defined solely by an active semiconductor substrate (not depicted in FIG. 4).

In the embodiment depicted in FIG. 3, an overmold compound 432 can encapsulate the MEMS substrate 412 and the semiconductor substrate 414, rather than providing a lid over these components. The overmold compound 432 can provide mechanical and environmental protection around the cavity regions, and in some embodiments, may require less space than a lid that requires additional clearance such as around wire bonds.

In some embodiments, the overmold compound 432 is physically coupled to an upper surface 434 of the LGA board 410 and provides a protective encapsulant surrounding the stacked substrates. The overmold compound 432 can include epoxy-based mold compound, silica-filled resin, or another mold compound suitable for standard semiconductor packaging operations. Overmolding can help reduce lateral dimensions and production cost, as well as reduce part count and can reduce manufacturing cost relative to a separate lid component while providing robust environmental protection and mechanical stability. Overmolding can also improve shock/drop reliability for compact modules, while the internal air volume of the back cavity 422 is maintained.

FIG. 5 depicts an exemplary ultrasonic transceiver including a multi-level stacked cap defining a back cavity in accordance with an embodiment of the present disclosure. In the embodiment of FIG. 5, ultrasonic transceiver 500 includes a land grid array (“LGA”) board 510, first and second MEMS substrates 512a, 512b, and a semiconductor substrate 514 stacked above the second MEMS substrate 512b, although it will be understood that components such as intervening layers or bonding layers may not be depicted, and that components may be added or removed. The first MEMS substrate 512a can include a first micromachined ultrasonic transducer (“MUT”) 516a suspended over a first front cavity 518a in the first MEMS substrate 512a. The first front cavity 518a can be exposed to an external environment through an acoustic port 520 extending through the LGA board 510. The second MEMS substrate 512b can include a second micromachined ultrasonic transducer (“MUT”) 516b suspended over a second front cavity 518b in the second MEMS substrate 512b with the first micromachined ultrasonic transducer (“MUT”) 516a suspended below the second front cavity 518b. The second front cavity 518b can enclose an air volume. In some embodiments, the air volume is sealed at approximately atmospheric pressure. In some embodiments, the air volume is sealed at a controlled pressure that is greater than vacuum and selected to tune acoustic loading and/or the compliance of the first and second MUTs 516a, 516b. In some embodiments, the air volume defined can be vented, such as through vent holes in the MUTs 516a and 516b. In some embodiments, the ultrasonic transceiver 500 is implemented in a stacked arrangement in which the semiconductor substrate 514 overlies the first and second MEMS substrates 512a, 512b and a lateral extent of the semiconductor substrate 514 is contained within an outer lateral perimeter of at least the upper MEMS substrate 512b and, in some embodiments, is contained within an outer lateral perimeter of the stacked MEMS substrates 512a, 512b.

The semiconductor substrate 514 can be either a combined (i.e., active and inactive layers) or active substrate as described herein, and that overlies the second MUT 516b and defines a back cavity 522 located on an opposite side of the second MUT 516b from the second front cavity 518b. The back cavity 522 can enclose an air volume. In some embodiments, this second enclosed air volume is sealed at a controlled pressure that is different from the first enclosed volume of front cavity 518b. Signal routing between the semiconductor substrate 514, the MEMS substrates 512a and 512b, and the LGA board 510 is provided by wirebonds 530 and/or redistribution layers, through-substrate vias, or combinations thereof (not shown in FIG. 5).

The ultrasonic transceiver 500 can additionally include a lid 532 surrounding the first and second MEMS substrates 512a, 512b and the semiconductor substrate 514 and physically coupled to an upper surface 534 of the LGA board 510 and defining a sealed enclosure 524. The lid 532 can provide mechanical protection, can mitigate contamination, and can provide a stable package volume for reliability under handling and environmental stress.

The stacked configuration of the semiconductor substrate 514 over the first and second MEMS substrates 512a, 512b can reduce lateral footprint relative to side-by-side die placement because the circuit-containing semiconductor area overlies the MEMS area. The back cavity 522 can be formed directly above the second MUT 516b while preserving the first front cavity 518a and port 520 acoustic access. In addition, the lid 532 can provide a robust outer protection structure while allowing the internal stacked structure to be assembled using established packaging processes.

In other embodiments, similar to FIG. 4, an overmold compound (not shown) can encapsulate the first and second MEMS substrates 512a, 512b and the semiconductor substrate 514. The overmold compound can provide mechanical and environmental protection around the sealed cavity region. The sealing structure can include a seal ring at the bond interface between the first MEMS substrate 512a and the semiconductor substrate 514, or a cap structure that forms a closed cavity prior to overmolding. In some embodiments, the overmold compound is physically coupled to an upper surface of the LGA board 510 and provides a protective encapsulant surrounding the stacked substrates. The overmold compound can include epoxy-based mold compound, silica-filled resin, or another mold compound suitable for standard semiconductor packaging operations. Overmolding can reduce part count and can reduce manufacturing cost relative to a separate lid component while providing robust environmental protection and mechanical stability. Overmolding can also improve shock/drop reliability for compact modules, while the internal seal maintains the back cavity 522 as an air volume.

In some embodiments, the first and second MUTs 516a, 516b are aligned along a common acoustic axis such that ultrasonic energy received from the external environment can be incident on both MUTs. The separation between the first and second MUTs 516a, 516b can be set based on an expected receive frequency band or the mechanical properties of the MUTs such that received waves at that frequency band can add constructively when sensed by the two MUTs. In some embodiments, signals from the two MUTs are combined (e.g., summed or beamformed) after time alignment to realize the constructive addition.

In some embodiments, the spacing is selected such that phase difference between the received ultrasonic waves at the two MUTs is within a target constructive range (e.g., within ±30 degrees, ±20 degrees, ±10 degrees, or another threshold) for a target frequency band. The phase difference can be determined based on a vertical separation distance between the first and second MUTs 516a, 516b, an expected speed of sound in an intervening medium, and a target center frequency or frequency band of operation. In some embodiments, the spacing corresponds to approximately an integer multiple of one-half wavelength (n·λ/2) in the intervening medium, including embodiments in which the spacing is selected to be within a tolerance range around n·λ/2 that accounts for manufacturing variation and frequency-dependent phase dispersion. In some embodiments, receive processing compensates for any residual phase difference due to spacing, such as by applying a phase correction or time alignment prior to summation, or by relying on the signal from the first MUT being within a tolerance range of n·180 degrees out of phase relative to the second MUT, in which case the signals from each MUT can be summed by a summing amplifier or differenced as inputs to a differential amplifier. By selecting the vertical separation and, where applicable, applying phase correction, the received signals from the first and second MUTs 516a, 516b can be combined such that correlated signal components add constructively while uncorrelated noise components combine incoherently, thereby increasing a signal-to-noise ratio relative to a single-MUT configuration.

In some embodiments, the first and second MUTs 516a, 516b are driven in transmit to produce a composite transmit output, and, like the receiving process, the relative phase difference between the driving signal for the first and second MUTs can be selected to ensure that the output signals of the two MUTs interfere constructively, increasing the emitted acoustic amplitude along a target axis. In some embodiments, the semiconductor substrate 514 includes electronic circuits (not shown) configured to process receive signals from both MUTs and combine them (e.g., sum, weighted sum, beamform) to increase received signal-to-noise ratio.

The dual-MUT arrangement can increase receive sensitivity and improve signal-to-noise ratio by constructive interference, which can improve detection accuracy and/or increase operating range. In addition, the dual-MUT arrangement can provide additional degrees of freedom for transmit/receive shaping (e.g., by driving MUTs with different amplitudes/phases) while retaining a compact stacked form factor.

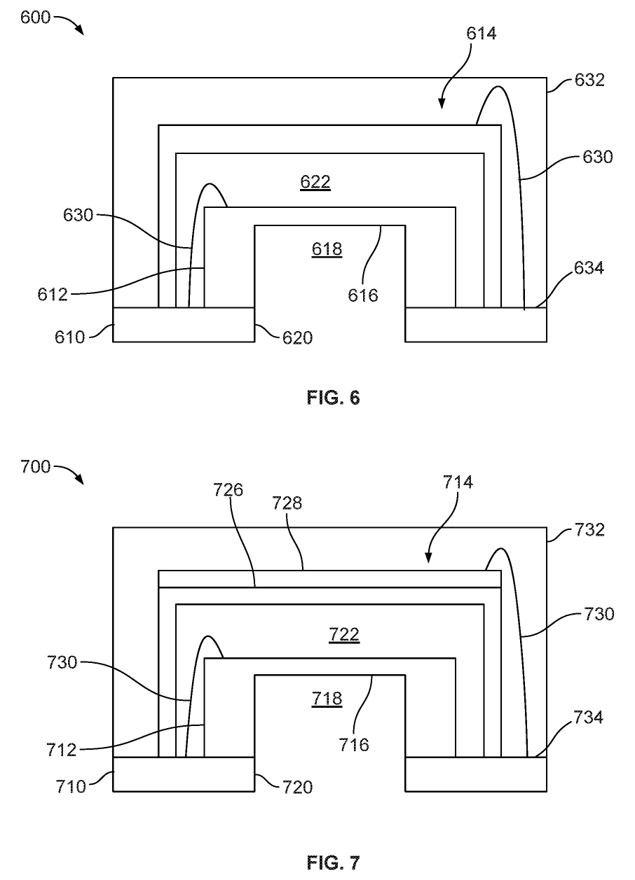

FIG. 6 depicts an exemplary ultrasonic transceiver including a stacked cap with processing circuitry defining a back cavity and overmold in accordance with an embodiment of the present disclosure. In the embodiment of FIG. 6 an ultrasonic transceiver 600 includes a land grid array (“LGA”) board 610, a MEMS substrate 612, and a semiconductor substrate 614 overlying and concentrically surrounding the MEMS substrate 612. The MEMS substrate 612 can include a micromachined ultrasonic transducer (“MUT”) 616 suspended over a front cavity 618 in the MEMS substrate 612, although it will be understood that components such as intervening layers or bonding layers may not be depicted, and that components may be added or removed. The front cavity 618 can be exposed to an external environment through an acoustic port 620 extending through the LGA board 610. In some embodiments, the ultrasonic transceiver 600 is implemented in a concentric arrangement in which the semiconductor substrate 614 overlies the MEMS substrate 612 and a lateral extent of the semiconductor substrate 614 extends beyond an outer lateral perimeter of the MEMS substrate 612 such that the semiconductor substrate 614 laterally surrounds at least a portion of the MEMS substrate 612.

The semiconductor substrate 614 can overlie the MUT 616 and define a back cavity 622 located on an opposite side of the MUT 616 from the front cavity 618. The back cavity 622 can enclose an air volume. In some embodiments, the air volume is sealed at approximately atmospheric pressure. In some embodiments, the air volume is sealed at a controlled pressure that is greater than vacuum and selected to tune acoustic loading and/or the compliance of the MUT 616. In some embodiments, the air volume can be vented, such as through vent holes in the MUT 616.

In some embodiments, the semiconductor substrate 614 includes an active substrate functioning as a cap, but which is not directly attached to the MUT 616. Instead the active substrate (e.g., an ASIC) is attached to the LGA board 610 at a predefined position, such as by direct bonding or stacking via one or more intermediate layers. In some embodiments, the bonded coupling defines a perimeter seal (e.g., a continuous ring) around the back cavity 622 such that the air volume is enclosed and remains stable over time. Signal routing between the semiconductor substrate 614, the MEMS substrate 612, and the LGA board 610 is provided by wirebonds 630 and/or redistribution layers, through-substrate vias, or combinations thereof (not shown in FIG. 6).

In this configuration, the MEMS cap is positioned relative to the MEMS substrate 612 such that the MEMS cap overlies the MUT 616 and cooperates with the MEMS substrate 612 to enclose the back cavity 622, including embodiments in which the MEMS cap is bonded to the LGA board 610 and a seal structure between the MEMS cap and the MEMS substrate defines the air-filled back cavity.

Similar to FIG. 4, an overmold compound 632 can encapsulate the MEMS substrate the semiconductor substrate 614, which along with LGA board 610 surrounds the MUT 616 with the exception of the port to the external environment. The overmold compound 632 can physically couple to an upper surface of the LGA board 610 and provides a protective encapsulant surrounding the stacked substrates. The overmold compound 632 can include epoxy-based mold compound, silica-filled resin, or another mold compound suitable for standard semiconductor packaging operations. Overmolding can reduce part count and can reduce manufacturing cost relative to a separate lid component while providing robust environmental protection and mechanical stability. Overmolding can also improve shock/drop reliability for compact modules, while the internal seal maintains the back cavity 622 as an air volume. Further, by utilizing highly controllable semiconductor fabrication processes to define the back cavity, the acoustic characteristics of the ultrasonic sensor can be modified such as to define acoustic resonance frequencies that are outside of the operating frequencies of the sensor.

In alternate arrangements, the ultrasonic transceiver 600 can additionally include a lid (not shown), similar to FIG. 3, surrounding the MEMS substrate 612 and the semiconductor substrate 614 and physically coupled to an upper surface 634 of the LGA board 610 and defining a sealed enclosure. The lid can provide mechanical protection, can mitigate contamination, and can provide a stable package volume for reliability under handling and environmental stress. In alternate embodiments, the arrangement of FIG. 6 can include a multi-MUT configuration like that shown in FIG. 5.

The concentric configuration of the semiconductor substrate 614 over the MEMS substrate 612 can reduce lateral footprint relative to side-by-side die placement because the circuit-containing semiconductor area overlies the MEMS area. It is understood that the configuration does not require a perfectly concentric arrangement. As used herein, the term “concentric” encompasses arrangements where the footprint of the semiconductor circumscribes the footprint of the MEMS without perfect concentricity. The back cavity 622 can be formed directly above the MUT 616 while preserving the front cavity 618 and port 620 acoustic access.

FIG. 7 depicts an exemplary ultrasonic transceiver including a stacked cap with an inactive layer and processing circuitry defining a back cavity and overmold in accordance with an embodiment of the present disclosure. In an embodiment depicted in FIG. 7, ultrasonic transceiver 700 includes a land grid array (“LGA”) board 710, a MEMS substrate 712, and a semiconductor substrate 714 overlying and concentrically surrounding the MEMS substrate 712, although it will be understood that components such as intervening layers or bonding layers may not be depicted, and that components may be added or removed. The MEMS substrate 712 can include a micromachined ultrasonic transducer (“MUT”) 716 suspended over a front cavity 718 in the MEMS substrate 712. The front cavity 718 can be exposed to an external environment through an acoustic port 720 extending through the LGA board 710. In some embodiments, the ultrasonic transceiver 700 is implemented in a concentric arrangement in which the semiconductor substrate 714 overlies the MEMS substrate 712 and a lateral extent of the semiconductor substrate 714 extends beyond an outer lateral perimeter of the MEMS substrate 712. In some embodiments, the semiconductor substrate 714 includes a wall that surrounds the outer lateral perimeter of the MEMS substrate 712, and the back cavity defined by the semiconductor substrate 714 surrounds the outer lateral perimeter of the MEMS substrate 712.

The semiconductor substrate 714 can overlie the MUT 716 and define a back cavity 722 located on an opposite side of the MUT 716 from the front cavity 718. The back cavity 722 can enclose an air volume. In some embodiments, the air volume is sealed at approximately atmospheric pressure. In some embodiments, the air volume is sealed at a controlled pressure that is greater than vacuum and selected to tune acoustic loading and/or the compliance of the MUT 716. In some embodiments, the air volume can be vented, such as through vent holes in the MUT 716.

In some embodiments, the semiconductor substrate 714 includes a non-active semiconductor substrate 726 (e.g., a MEMS cap) and an active substrate 728 (e.g., an ASIC) stacked on the non-active substrate, such as by bonding. The stacked substrates define a perimeter seal (e.g., a continuous ring) around the back cavity 722 such that the air volume is enclosed and remains stable over time. Signal routing between the semiconductor substrate 714, the MEMS substrate 712, and the LGA board 710 is provided by wirebonds 730 and/or redistribution layers, through-substrate vias, or combinations thereof (not shown in FIG. 7).

Similar to FIG. 4, an overmold compound 732 can encapsulate the MEMS substrate 712 and the semiconductor substrate 714. The overmold compound 732 can provide mechanical and environmental protection around the sealed cavity region. The sealing structure can include a seal ring at the bond interface between the MEMS substrate 712 and the semiconductor substrate 714, or a cap structure that forms a closed cavity prior to overmolding. Further, by utilizing highly controllable semiconductor fabrication processes to define the back cavity, the acoustic characteristics of the ultrasonic sensor can be modified such as to define acoustic resonance frequencies that are outside of the operating frequencies of the sensor.

In some embodiments, the overmold compound 732 is physically coupled to an upper surface of the LGA board 710 and provides a protective encapsulant surrounding the stacked substrates. The overmold compound 732 can include epoxy-based mold compound, silica-filled resin, or another mold compound suitable for standard semiconductor packaging operations. Overmolding can reduce part count and can reduce manufacturing cost relative to a separate lid component while providing robust environmental protection and mechanical stability. Overmolding can also improve shock/drop reliability for compact modules, while the internal seal maintains the back cavity 722 as an air volume.

In alternate arrangements, the ultrasonic transceiver 700 can include a lid (not shown), similar to FIG. 3, surrounding the MEMS substrate 712 and the semiconductor substrate 714 and physically coupled to an upper surface 734 of the LGA board 710 and defining a sealed enclosure. The lid can provide mechanical protection, can mitigate contamination, and can provide a stable package volume for reliability under handling and environmental stress. In alternate embodiments, the arrangement of FIG. 7 can include a multi-MUT configuration like that shown in FIG. 5.

The concentric configuration of the semiconductor substrate 714 over the MEMS substrate 712 can reduce lateral footprint relative to side-by-side die placement because the circuit-containing semiconductor area overlies the MEMS area. The back cavity 722 can be formed directly above the MUT 716 while preserving the front cavity 718 and port 720 acoustic access.

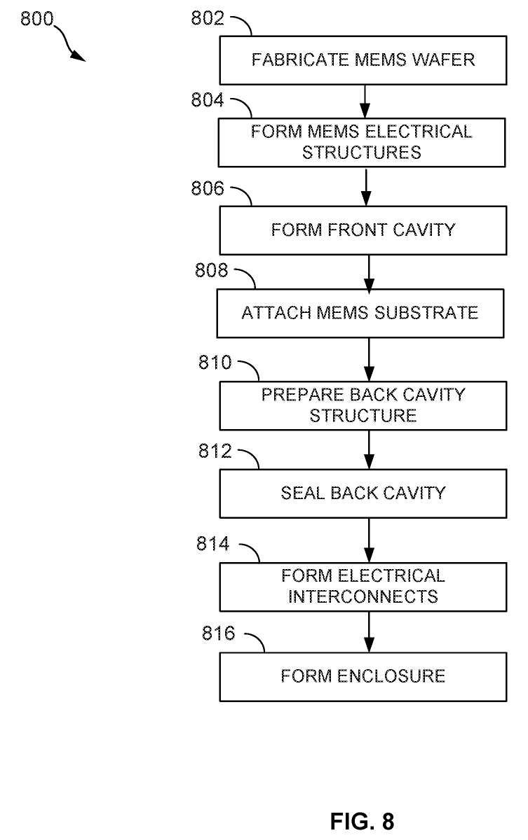

FIG. 8 depicts exemplary steps of a fabrication process for an ultrasonic transceiver in accordance with embodiments of the present disclosure, including the embodiments described above with reference to FIGS. 2–7. The steps are illustrative. In various implementations, steps can be performed in a different order, combined, subdivided, repeated, or omitted depending on selected materials, wafer flows, bonding approaches, interconnect schemes, and packaging constraints. The fabrication and assembly process 800 includes, for example, formation of front cavities and acoustic ports, formation and sealing of air-filled back cavities, selection and formation of perimeter seal structures, stacked substrate sequencing, and electrical interconnect topologies.

Process 800 begins at step 802, where a MEMS wafer is fabricated to define a MEMS substrate (e.g., MEMS substrate 212, 312, 412, 512a/512b, 612, or 712) including one or more micromachined ultrasonic transducers (“MUTs”) (e.g., MUT 216, 316, 416, 516a/516b, 616, or 716). In some embodiments, forming the MUT at step 802 includes forming a membrane region and associated transduction structures. In some embodiments, the MUT is formed as a single element. In other embodiments, the MUT is formed as an array of elements arranged laterally across the MEMS substrate.

At step 804, electrical structures on the MEMS substrate are formed, including routing metallization, bond pads, and passivation layers. In some embodiments, step 804 includes forming redistribution layers, under-bump metallization, or other pad finishes to support a selected interconnect scheme such as wirebonding or flip-chip bonding. In some embodiments, step 804 further includes forming features that electrically isolate the MUT membrane region from surrounding structures, and/or forming guard structures and passivation to improve reliability.

At step 806, a front cavity and an acoustic communication path are formed or defined. In some embodiments, the front cavity (e.g., front cavity 218, 318, 418, 518a, 618, or 718) is formed by backside etching of the MEMS wafer to create a recess cavity or through-etch cavity beneath the MUT membrane. In embodiments that use a package substrate acoustic port, step 806 further includes providing a package substrate, such as an LGA board (e.g., LGA board 210, 310, 410, 510, 610, or 710), and forming or defining an acoustic port (e.g., acoustic port 220, 320, 420, 520, 620, or 720) extending through the package substrate by drilling, laser ablation, etching, molding, or another suitable technique. In some embodiments, step 806 includes forming metallization and external pads on the package substrate for subsequent electrical connection to external circuitry.

At step 808, the MEMS substrate is attached to the package substrate. In some embodiments, attachment includes an adhered coupling (e.g., epoxy or polymer adhesive) selected to reduce outgassing and to maintain stable adhesion under thermal cycling. In embodiments having an acoustic port, step 808 further includes aligning the front cavity of the MEMS substrate with the acoustic port of the package substrate to provide acoustic communication between the front cavity and the external environment.

At step 810, a cavity-defining structure is provided and prepared to define a back cavity on an opposite side of the MUT from the front cavity. In some embodiments, the cavity-defining structure includes a semiconductor substrate that will overlie the MUT (e.g., semiconductor substrate 214, 314, 414, 514, 614, or 714). In some embodiments, step 810 includes forming a cavity recess in the cavity-defining structure to provide clearance for MUT motion and to define at least a portion of the back cavity geometry. In some embodiments, step 810 includes forming or patterning a seal region around a perimeter of the cavity recess (or around a perimeter of a cavity region) that will later cooperate with a corresponding surface of the MEMS substrate to form a perimeter seal.

At step 812, the cavity-defining structure is bonded relative to the MEMS substrate to form and seal a back cavity enclosing an air volume. In some embodiments, the air volume defined can be vented, such as through vent holes in the MUT defining in part the back cavity. In some embodiments, bonding is performed such that the back cavity is a non-vacuum cavity enclosing an air-filled volume at approximately atmospheric pressure or at a controlled pressure materially greater than vacuum. In some embodiments, the bond includes a bonded coupling (e.g., adhered coupling, solder coupling, eutectic coupling, glass frit bonding, anodic bonding, fusion bonding, or another suitable bond) that defines a perimeter seal (e.g., a continuous ring) around the back cavity to enclose the air volume and maintain stability over time.

The implementation of steps 810 and 812 can vary among embodiments while remaining within the scope of process 800. For example, for embodiments such as FIG. 2, step 810 can include preparing a semiconductor substrate (e.g., semiconductor substrate 214) with an optional cavity recess and a seal region, and step 812 can include bonding that semiconductor substrate directly to the MEMS substrate (e.g., MEMS substrate 212) to define the back cavity (e.g., back cavity 222). For embodiments such as FIG. 3, step 810 can include preparing an active semiconductor substrate such as an ASIC, with a cavity recess and a seal region, and step 812 can include bonding the ASIC to the MEMS substrate (e.g., MEMS substrate 312) so that the ASIC functions as a cap to define the back cavity (e.g., back cavity 322). For embodiments such as FIG. 6, step 812 can include bonding a cavity-defining portion of the semiconductor substrate (e.g., MEMS cap portion) to the LGA board 610 and positioning the MEMS substrate 612 relative thereto such that the semiconductor substrate overlies the MUT 616 and cooperates with the MEMS substrate 612 to define the back cavity 622. For embodiments such as FIG. 7, step 810 can include preparing a semiconductor substrate (e.g., semiconductor substrate 714) that laterally extends beyond and concentrically surrounds the MEMS substrate (e.g., MEMS substrate 712), and step 812 can include bonding to define the back cavity (e.g., back cavity 722) while also providing a perimeter seal and, in some embodiments, a stress-isolation wall or perimeter structure.

In some embodiments, where the active circuitry is provided as a separate active substrate (e.g., an ASIC die) and is not integrated with the cavity-defining structure, the active substrate is attached in a stacked arrangement on the MEMS, which in turn functions as a MEMS cap. For example, in embodiments in which a MEMS cap forms a non-active substrate, step 814 can include attaching an active substrate above the non-active substrate after formation of the back cavity. In some embodiments, attachment is by adhered coupling, a solder coupling, a eutectic coupling, glass frit bonding, anodic bonding, fusion bonding, or another suitable bond (e.g., glue). In other embodiments, such as FIG. 3, a monolithic active structure is provided, and step 814 can be omitted.

At step 814, electrical interconnects are formed among the MEMS substrate, the semiconductor substrate (including any non-active and active substrates), and the package substrate. In some embodiments, step 814 includes forming wirebonds from bond pads on the active substrate to bond pads on the package substrate and/or bond pads on the MEMS substrate. In other embodiments, step 814 includes forming flip-chip interconnects, micro-bumps, copper pillars, or through-substrate vias to provide vertical interconnect and to reduce parasitic inductance. In some embodiments, step 814 further includes applying underfill or localized encapsulant to improve reliability of the formed interconnects.

At step 816, a protective enclosure is formed around the assembled stack while preserving the acoustic path. In some embodiments, step 816 includes attaching a lid (e.g., lid 232, 332, 532) to the package substrate to surround the MEMS substrate and the semiconductor substrate and to define a sealed enclosure. In other embodiments, step 816 includes applying an overmold compound (e.g., overmold compound 432, 632, or 732) to encapsulate the MEMS substrate and the semiconductor substrate and to physically couple to an upper surface of the package substrate. In some embodiments, when overmolding is used, the back cavity seal formed in step 812 is configured to resist mold compound intrusion, such as by using a seal ring geometry or seal material selected for mold compatibility. In some embodiments, where a semiconductor substrate surrounds the MEMS substrate as in FIG. 7, the surrounding perimeter structure provides a standoff and/or barrier that reduces the transfer of molding-induced mechanical stress to the MEMS substrate and the MUT region and further reduces the risk of mold compound intrusion into a region adjacent to the perimeter seal.

After fabrication is completed, a final test, verification, and calibration can be performed. In some embodiments, testing of transmit response, receive sensitivity, electrical continuity, and cavity integrity (e.g., leak testing of the back cavity seal) can be performed. In embodiments such as FIG. 5, calibration can be performed for combining signals from multiple MUTs, including determining phase correction or timing alignment to promote constructive summation of received signals for improved signal-to-noise ratio. In some embodiments, calibration constants are stored in non-volatile memory or otherwise associated with the device for use during operation.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. An ultrasonic transceiver, comprising:
a microelectromechanical system (MEMS) substrate comprising a micromachined ultrasonic transducer (MUT) suspended over a front cavity in the MEMS substrate that is exposed to an external environment; and
a semiconductor substrate comprising a cap that is physically secured relative to the MEMS substrate, overlying the MUT, and defining a back cavity that encloses an air volume and is located on an opposite side of the MUT from the front cavity.

2. The ultrasonic transceiver of claim 1, wherein the semiconductor substrate comprises a non-active substrate and an active substrate containing electronic circuits stacked above the non-active substrate.

3. The ultrasonic transceiver of claim 2, wherein the non-active substrate forms the cap.

4. The ultrasonic transceiver of claim 1, wherein the semiconductor substrate comprises a monolithic body having a first portion containing electronic circuits and a second portion that forms the cap and defines the back cavity.

5. The ultrasonic transceiver of claim 1, wherein the MEMS substrate forms a first MEMS substrate, the MUT forms a first MUT, and the front cavity forms a first front cavity, and further comprising a second MEMS substrate comprising a second MUT suspended over a second front cavity in the second MEMS substrate, the second MEMS substrate stacked on the first MEMS substrate and the second front cavity being disposed between the first MUT and the second MUT.

6. The ultrasonic transceiver of claim 5, wherein a vertical separation between the first MUT and the second MUT is configured to create constructive acoustic interference of ultrasonic waves received by the first MUT and the second MUT and thereby increase a signal-to-noise ratio of a received ultrasonic signal relative to a single-MUT configuration during a receive operation.

7. The ultrasonic transceiver of claim 5, wherein a vertical separation between the first MUT and the second MUT is configured to create constructive acoustic interference of ultrasonic waves transmitted by the first MUT and the second MUT during a transmit operation.

8. The ultrasonic transceiver of claim 5, wherein the semiconductor substrate is bonded to an upper surface of the second MEMS substrate.

9. The ultrasonic transceiver of claim 1, wherein the semiconductor substrate is physically coupled to an upper surface of the MEMS substrate.

10. The ultrasonic transceiver of claim 9, wherein the semiconductor substrate is physically coupled to the upper surface of the MEMS substrate by a bonded coupling.

11. The ultrasonic transceiver of claim 10, wherein the bonded coupling comprises an adhered coupling.

12. The ultrasonic transceiver of claim 1, further comprising a land grid array (LGA) board, wherein the MEMS substrate is physically coupled to an upper surface of the LGA board.

13. The ultrasonic transceiver of claim 12, further comprising a lid surrounding the MEMS substrate and the semiconductor substrate and physically coupled to the upper surface of the LGA board.

14. The ultrasonic transceiver of claim 12, further comprising an overmold compound encapsulating the MEMS substrate and the semiconductor substrate and physically coupled to the upper surface of the LGA board.

15. The ultrasonic transceiver of claim 1, wherein a lateral extent of the semiconductor substrate is contained within an outer lateral perimeter of the MEMS substrate.

16. The ultrasonic transceiver of claim 1, wherein a lateral extent of the semiconductor substrate extends beyond an outer lateral perimeter of the MEMS substrate.

17. The ultrasonic transceiver of claim 16, wherein the semiconductor substrate comprises a wall surrounding the outer lateral perimeter of the MEMS substrate and the back cavity surrounds the outer lateral perimeter of the MEMS substrate.

18. A method of fabricating an ultrasonic transceiver, comprising:
providing a microelectromechanical system (MEMS) substrate comprising a micromachined ultrasonic transducer (MUT) suspended over a front cavity in the MEMS substrate, the front cavity being configured to be exposed to an external environment;
providing a semiconductor substrate comprising a cap defining a cavity recess;
positioning the semiconductor substrate such that the semiconductor substrate overlies the MUT; and
physically securing the semiconductor substrate relative to the MEMS substrate such that the cap cooperates with the MEMS substrate to define a back cavity that forms an air volume on an opposite side of the MUT from the front cavity.

19. The method of claim 18, further comprising physically coupling the MEMS substrate to an upper surface of a land grid array (LGA) board.

20. The method of claim 19, further comprising physically coupling the semiconductor substrate to the upper surface of the LGA board.
